(19) United States
(12) Patent Application Publication
(10) Pub. No.: US 2013/0135832 A1
(43) Pub. Date: May 30, 2013

(54) EXPLOSION PROTECTED CIRCUIT BOARD ASSEMBLY

(71) Applicants: Jörg Stritzelberger, Ohringen (DE); Fritz Frey, Kunselsau (DE)

(72) Inventors: Jörg Stritzelberger, Ohringen (DE); Fritz Frey, Kunselsau (DE)

(73) Assignee: R. STAHL SCHALTGERÄTE GMBH, Waldenburg (DE)

(21) Appl. No.: 13/643,785

(22) PCT Filed: Apr. 19, 2011
(86) PCT No.: PCT/EP2011/055452

§ 371 Date: Jan. 10, 2013

(30) Foreign Application Priority Data
Apr. 29, 2010 (DE) 10 2010 018 784.4

(51) Int. Cl. H05K 5/02

(52) U.S. Cl. CPC H05K 5/02
USPC 361/752

(57) ABSTRACT

An explosion protected circuit board assembly that includes a circuit board having a carrier plate with conductive strips and at least one electrical component thereon. The circuit board assembly includes a housing part that defines a hollow space encasing the electronic component in intrinsically safe fashion while preventing flame transmission from the electrical component to the outside environment. In an alternative embodiment, housing parts defining hollow electrical component receiving spaces are mounted on opposite sides of the circuit board, with the components being electrically interconnected.

### FIELD OF THE INVENTION

The invention relates to a circuit board assembly that is protected against explosion.

### BACKGROUND OF THE INVENTION

The invention relates to electronic assemblies that are suitable for installation in an environment in which an explosive atmosphere exists, at least occasionally or also frequently. In particular, the invention relates to a circuit board assembly comprising at least one non-intrinsically safe circuit, i.e., a circuit, wherein the occurring voltages and currents can lead to the ignition of a gas mixture that—at least in an error situation—is capable of exploding.

In order to protect electronic installations against explosion it has been known to accommodate them in a housing that, for example, communicates with the ambient air via a sintered metal disk. In that regard, publication DE 10 2005 050 914 B4 discloses a gas metering device comprising a detector cell. The detector cell contains a thin, helical platinum wire that is enclosed in a small ceramic bead having a catalytically active surface, in particular, of precious metals. The platinum wire is heated in a targeted manner. Explosive gases are catalytically combusted in a controlled manner on the heated detector element. The detector cell has its own housing that communicates with the ambient air via a sintered metal disk.

Furthermore, it has been known to accommodate electronic units in pressure-proof encapsulated housings. In that regard, publication DE 20 319 489 U1 discloses such a multi-component housing.

It further has been known from publication DE 10 024 427 A1 to accommodate electronic assemblies inside an electrical installation—such as, for example, a lamp—in a partial housing, and to pot them there. Such potting prevents the contact of the electronic components and the circuit board with ambient gases.

The potting of circuit boards and their electrical components has been found to be fundamentally effective. However, it also brings about problems. For example, such potting makes the repair of the electronic assembly difficult. If electromechanical components are present, they must have a closed design in order to prevent the casting compound from penetrating into the components, for example a relay. It is also possible for mechanical tensions to form between the casting compound and the conductor strips of the circuit board that can result in the malfunction of the assembly. Furthermore, the production of a casting compound represents an expensive and complex manufacturing process. In addition, for the potting compound to qualify qualitatively, extensive and time-consuming tests are required, thus slowing the development process.

### OBJECTS AND SUMMARY OF THE INVENTION

It is an object of the present invention to provide a relatively simple and economical circuit board assembly that is adapted for reliable usage in explosive atmospheres.

The circuit board assembly in accordance with the invention comprises a circuit board to which is mounted at least one electrical, electromechanical or electronic component that is part of a non-intrinsically safe circuit. Arranged on the circuit board is a housing part that defines a hollow space that accommodates the element, encapsulating it in an explosion-proof manner. The housing part has a closed edge that is supported by the circuit board. In doing so, the housing part delimits a gas volume that is closed on five sides by the housing part and on the sixth side by the circuit board. In doing so, the circuit board extends, at least in part, beyond the edge of the housing part. In other words the footprint of the housing part is preferably smaller than the contour of the circuit board. However, it is also possible to install the circuit board in a housing opening of the housing part in order to enclose the circuit board.

Outside the housing part, the circuit board may be loaded with additional electronic, electrical or electromechanical components. In doing so, it is useful to be able to arrange critical components that could potentially lead to an ignition of explosive gas mixtures within the housing part and the other components that do not pose an ignition hazard outside the housing part.

The housing part may be fastened to the circuit board itself so that the circuit board forms a sixth housing wall. It is possible for several such equally or differently configured housing parts to be arranged at or on the circuit board in order to form several spaces that are delimited relative to the environment.

Furthermore, it is possible to arrange an additional housing part on the side of the circuit board that faces away from the housing part. Preferably, said additional housing part has the same footprint as the first-mentioned housing part. The two housing parts may be connected to each other by one or more fastening means extending through the circuit board. Such fastening means, for example, may be detent fingers, detent lugs, screws, rivets, pins glued into boreholes, or the like. In this way, a limited space is created through which extends the circuit board.

Electrical contacting of the electrical components arranged in the housing part may be accomplished by conductor strips that are arranged on the side of the circuit board that faces away from the housing part. It is also possible to provide conductor strips that extend between the circuit board and the housing part or extend within the circuit board. Alternatively, contact means may be provided on the housing part that contact conductor strips of the circuit board.

The hollow space of the housing is preferably clear, i.e., does not contain any casting compound. However, in order to reduce the volume it may be partially or completely filled with loose material, for example, glass spheres.

If needed, the housing part may be provided with a gas-permeable opening that is closed by means such as metal nets, metal screens, sintered metal plates, or the like, that prevent a flame transmission. The housing part may consist of a synthetic material or a metal. Housing parts of a synthetic material may be transparent—at least in sections but also fully—in order to allow, for example, signaling devices or the like to be visible from the outside. Metal housings may be used for the removal of heat developed by electronic or electrical components.

A casting compound may be applied to the circuit boards in accordance with the invention, and particularly, outside the housing. The casting compound may be applied to one or both sides of the circuit board. However the interior space of the housing part is kept as free as possible of such a compound.

The circuit board assembly in accordance with the invention may be designed so as to be maintenance-friendly. For example, the fastening means that are used for fastening the housing part to the circuit board or to an oppositely arranged housing part may be releasable connecting means such as, for example, screws. Thus, access to the encased components is possible for maintenance or repair purposes.

A casting compound aging that could lead to failures of the electrical circuit is precluded due to the omission of a casting compound in the interior space of the housing part.

The housing part that delimits a partial space on the circuit board may itself be a part of a housing that accommodates or encloses the circuit board such as, for example, an apparatus housing. In other words one or more pocket-like structures may be provided on the inside of one housing wall of such an apparatus housing, whereby the circuit board can be mounted to said pocket-like structures so that said circuit board forms a seal with the edge of the respective pocket-like structure. The respective pocket then accommodates components that are loaded on the circuit board and that are to be protected.

Other objects and advantages of the invention will become apparent upon reading the following detailed description and upon reference to the drawings.

### BRIEF DESCRIPTION OF THE DRAWINGS

FIG. 1 is a schemattic perspective of an illustrated explosion protected circuit board assembly in accordance with the invention;

FIG. 2 is an enlarged vertical fragmentary section the circuit board assembly shown is FIG. 1; and

FIGS. 3-8 are vertical sections of further alternative embodiments of circuit board assemblies according to the invention.

While the invention is susceptable of various modifications and alternative constructions, certain illustrative embodiments thereof have been shown in the drawings and will be described below in detail. It should be understood, however, that there is no intention to limit the invention to the specific forms disclosed, but on the contrary, the intention is to cover all modificatons, alternative constructions, and equivalents falling within the spirit and scope of the invention.

### DETAILED DESCRIPTION OF THE PREFERRED EMBODIMENTS

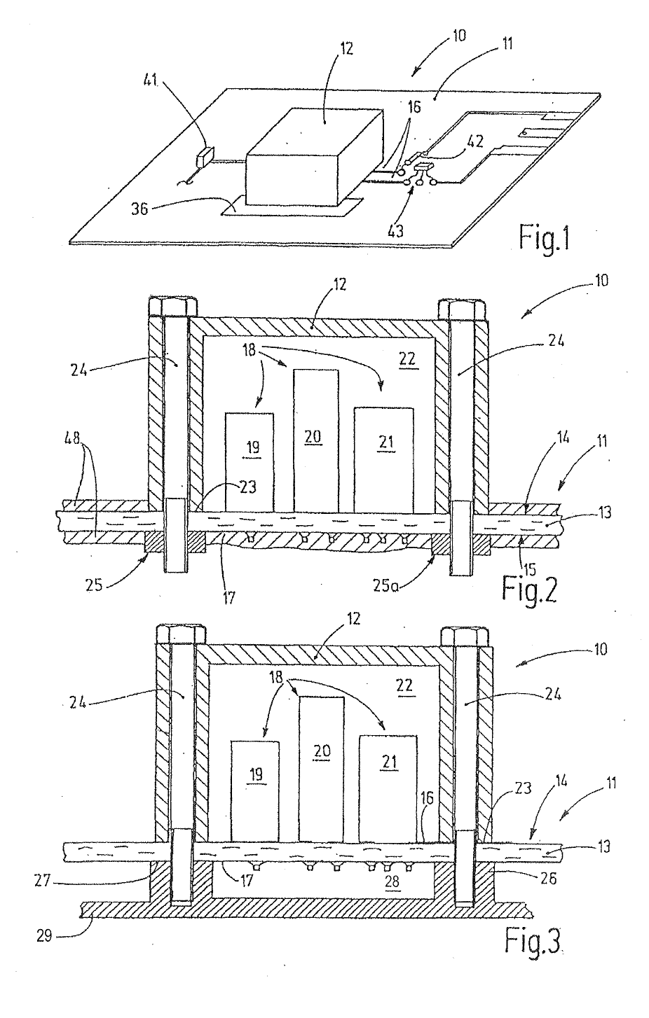

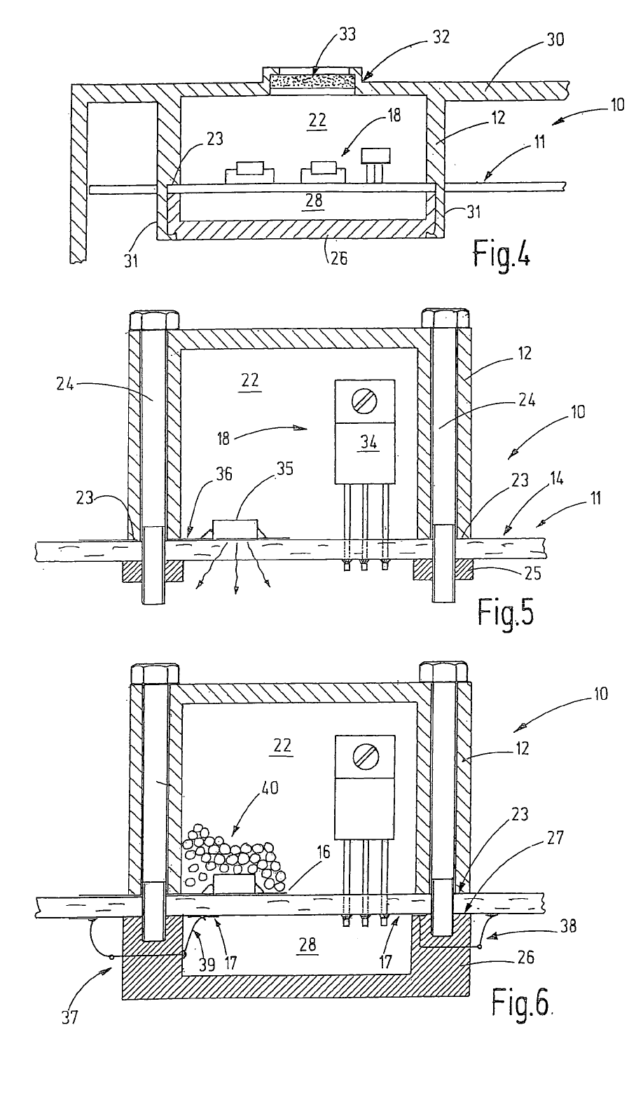

Referring now more particularly to FIGS. 1 and 2 of the drawing, there is shown an illustrative circuit board assembly 10 in accordance with the invention comprising a circuit board 11 and at least one housing part 12. The circuit board 11 comprises a plate-shaped carrier 13 (see FIG. 2) having a first flat side 14 and a second flat side 15. The circuit board is provided with appropriate conductor strips arranged on the carrier 13. More particularly conductor strips 16 may be provided on at least one of the two flat sides 14, 15. Additional conductor strips 17 may be provided on the other flat side.

The conductor strip 16 or 17 form a non-intrinsically safe circuit with at least one electrical component 18. The electrical component 18 may be an energy-storing component such as, for example, an inductor or a capacitor, a transformer; or a dissipative component such as, for example, an electrical resistor; an electronic component such as, for example, a diode a Z-diode, a transistor, an integrated circuit; or an electro-optical component such as, for example, a light-emitting diode, a connecting terminal, a female connector or the like. Additionally, the electrical component may be an electromechanical component such as, for example, a relay or the like. Referring to the exemplary embodiment as in FIG. 2, the electrical components are shown as an electrical resistor 19, a capacitor 20 and a transformer 21. Due to the voltages and currents occurring at the components 18 and/or due to the energy stored in the components, the associate electrical circuits or circuits are non-intrinsically safe.

The housing part 12 defines a hollow space 22 on five sides. To accomplish this, the housing part 12 is preferably designed without openings. Its closed edge 23 is preferably configured as a planar surface that is supported by the first flat side 14 and fastened thereto, such as by glue. The housing part 12 further may consist of a synthetic material and is held on the circuit board 11 by suitable fastening means. In the present exemplary embodiment, this is accomplished with several fastening screws that extend through suitable channels of the housing part 12 and the circuit board 11. They may be secured on the flat side 15 that faces away from the housing part 12, for example, by nuts 25. Optionally, the flat side 14 may also be provided with a casting compound. Such a casting compound 48 may also, or alternatively, be applied to the flat side 15.

In this embodiment, there are electrical components 18 which are potentially active as ignition sources enclosed in the hollow space 22. The wall thickness and the strength of the housing part 12 as well as that of the body 13 of the circuit board 11 is such that a detonation or explosion inside the hollow space 22 cannot result in an escape of the flames or hot particles from the hollow space 22. When an explosion occurs in the hollow space 22, such an explosion is restricted to the hollow space 22 and does not lead to an ignition of explosive gases that might potentially be present outside the hollow space 22. In other words the circuit board or the part of the circuit board 11 delimited by the edge 23 of the housing 12 forms a part of the Ex-d housing, with the other part being represented by the housing part 12.

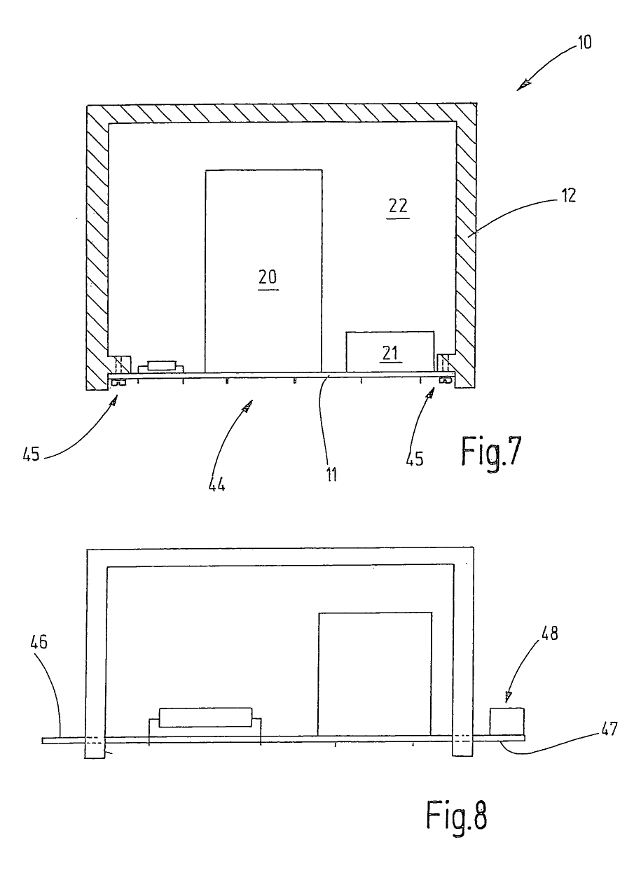

FIG. 3 shows a modified embodiment of the circuit board assembly 10, wherein the previous description using the already introduced reference signs again apply.

In addition to the housing part 12, there is another housing part 26. While the edge 23 of the housing part 12 is seated on the flat side 14 of the body 13 of the circuit board 11, the edge 27 of the housing part 26 abuts against the appropriate flat side 15. Preferably, the edges 23, 27 are essentially congruent and are configured as uninterrupted plane surfaces. The housing part 26, like the housing part 12, may be made of synthetic material and provided with threaded bores for receiving the fastening screws 14. Matching passage openings of the upper housing part 12 and the circuit board 11 are in alignment with the threaded bores of the housing part 26.

The housing part 26 may bridge a hollow space 28 that is able to accommodate at least one electrical component. However, as is shown by FIG. 3, said hollow space may also only bridge the solder connections of the electrical components 18, or it may even be empty.

The conductor strips 16 present on the circuit board 11 may extend from the hollow space 22 between the edge 23 and the carrier 13. Additionally or alternatively, conductor strips 17 may also extend from the hollow pace 28 between the edge 27 and the body 13 or within the circuit board.

A casting compound 48 may optionally be provided outside the hollow spaces 22, 28. At least one of the housing parts 12, 26 may be part of a bigger housing encasing the circuit board 11. This is shown in an exemplary manner by FIG. 3 for the lower housing part 26 that is arranged like a mounting base on the inside of an apparatus wall 29.

Additional modifications are possible. FIG. 4 shows the embodiment of the upper housing part 12 as a part of an apparatus housing 30. The circuit board 11 is arranged in this apparatus housing. Again, non-intrinsically safe circuits are arranged in a space that is delimited by the apparatus housing 30. This space is formed by the two hollow spaces 22, 28. In this exemplary embodiment, the housing part 26 is designed as a snap-on lid. The detent fingers 31 project from the edge 23 of the housing part 12, with the detent fingers engaging into corresponding openings of the circuit board 11. The detent fingers 31 come into engagement with corresponding detent recesses of the housing part 26, as a result of which the circuit board 11 is held between the two housing parts 12, 26. The type of connection of the two housing parts 12, 26 shown by FIG. 4 can also be effectively used in the other embodiments comprising two housing parts 12, 26.

At least one of the two housing parts 12, 26—in FIG. 4 the housing part 12, for example—can be provided with a pressure relief opening 32 that terminates in the interior of the apparatus housing 30 or—as shown in FIG. 4—toward the outside. The pressure relief opening 32 establishes a gas-permeable connection between the hollow space 22 and the environment. A transmission-arresting body 33, e.g., in the form of a sintered metal body or a body consisting of metal fibers or a similar means that allows a gas exchange, but not a flame transmission due to the existing narrow passage channels, is installed in the pressure relief opening 32. Such a pressure relief opening with the body 23 arranged therein also can be used in each of the embodiments described herein.

FIG. 5 illustrates another embodiment of the circuit board assembly 10, the special feature of this embodiment being that the housing part 12 consists of metal. Consequently, said housing part may act as a cooling body for a component 18 arranged in the hollow space 22, which may, for example, be a high load resistor or a transistor 34 connected with the housing part 12 in a thermally conductive manner. Other than that, the description as in FIG. 2 applies correspondingly.

In all of the embodiments of the circuit board assembly 10 in accordance with the invention the circuit board 11 may be transparent as depicted by the example of FIG. 5. This opens up the possibility of using the circuit board 11 as a light-transmitting surface, for example for an LED 35 arranged in the hollow space 22 on the flat side 14. In this case, the LED 35 is preferably a light emitting diode such as a reverse mount LED for emitting light toward the assembly surface.

The LED 35 or any other electrical components that tends to heat up can be cooled by using larger copper surfaces 36 that are arranged on the flat side 14. As illustrated, these copper surfaces 36 may extend under the edge 23 and beyond, i.e. out of the hollow space 22 toward the outside. Hence, the copper surface 26 may extend beyond the housing part 12 toward the outside, as indicated in FIG. 1. In this manner, the copper surface 36 itself may act as the cooling surface. If the housing part 12 is designed so as to be thermally conductive, it may also be disposed for cooling the LED 35 or another electrical component due to the thermal contact with the copper surface 36.

FIG. 6 shows another embodiment, based on the embodiment of FIG. 3. Optionally, the housing part 26 may be a part of an apparatus housing or, as shown, be separate. The housing parts 12 and/or 26 may be provided with contact means 37, 38 in order to contact the conductor strips 16 or 17. Such contact means are, for example, conductors embedded in the housing part 26 and connected, e.g., soldered, on the outside to the conductor strips or other lines. In this case, the contact means 37, 38 are connected to the conductor strips 17, for example, in the hollow space 28, by suitable connecting means, for example contact springs 39. Alternatively, the electrical connection between a conductor strip 17 and the contact means 38 may also take place within the edge 27, as is schematically shown on the right side of FIG. 6.

In each of the above-described embodiments that the hollow space 22 and, if existing, the hollow space 28 may be filled, as needed, with a loose filler material, for example glass spheres 40 that are disposed to reduce the gas volume in the hollow space 22 or 28. As needed, filling openings for pouring in the glass spheres 40 or another filler material may be provided on the housing part 12, housing part 28 or in the circuit board 11. The openings may be provided with closing means such as, for example, screw plugs. In the embodiment as in FIG. 4, the glass spheres 40 may optionally also be filled through the pressure relief opening 32 into the hollow space 22. This is the case, for example when the body 33 is held in a fitting that can be inserted into the apparatus housing 30 from the outside, for example, a screw socket.

Each of the above-described circuit board assemblies 10 comprises at least one electrical component 18 that is arranged in the at least one housing part 12. Additional components 41, 42, 43 may be provided (FIG. 1), these being arranged on the circuit board 11 outside the housing part 12. Preferably, the components 41, 42, 43 are parts of intrinsically safe circuits or electrical circuits that, even in an error situation, cannot act as an ignition source for an explosive atmosphere.

By dividing the electrical circuit arranged on the circuit board 11 into intrinsically safe parts that are arranged outside the housing part 12 and non-intrinsically safe parts that are arranged inside the hollow space 22, the volume enclosed by the housing protecting against explosion can be substantially reduced in comparison with an explosion-safe encasing of the entire circuit board 11. The hollow space 22 has a smaller volume than the interior of the housing that accommodates the entire circuit board 11. Consequently, in the case of an explosion triggered by one of the electrical components 18, the exploding gas volume is substantially reduced. Accordingly, the housing part 12 can be a simpler, smaller and more cost-effective housing compared to housings that encase the entire circuit board 11.

FIG. 7 illustrates another embodiment of the circuit board assembly 10. The description hereinabove applies correspondingly with the use of the same reference signs. The housing part 12 is provided with a housing opening 44 that is closed by the circuit board 11. The circuit board may be held by screws 45 that are screwed into corresponding threaded bores of the housing part 12. Instead of the fastening screws, it is also possible to use other connecting means. For example, the housing part 12 may be glued to the circuit board 11. An appropriate casting compound also may be applied for covering the outside of the circuit board 11 and adjoining the part of the housing part that projects beyond the circuit board 11.

As in FIG. 8, the circuit board 11 may also have one or more extensions 46, 47 that extend through corresponding recesses of the housing wall of the housing part 12. These extensions 46, 47 may carry additional components, connecting elements 48 or the like. Also in the case of this embodiment, a casting compound may be applied to or on the circuit board 11. The circuit board 11 may be screwed to the housing part, glued to it or otherwise connected. Other than that, the description hereinabove similarly applies.

From the foregoing, it can be seen that the invention is suitable for electronic assemblies that are used in areas that pose an explosion hazard, i.e., in areas in which an explosive atmosphere may occur. In conjunction with this, it is possible to use non-intrinsically safe circuits with the electrical components 18 thereof being encased by at least one housing part 12 held on the circuit board 11, thus producing an Ex-d space. In doing so, the circuit board may close the housing part 12 on one side. Alternatively, a second housing part 26 may be provided, in which case the housing parts 12, 26 then accommodate the circuit board 11 between them. In doing so, the circuit board may act as a conductive passage and also be a component of the Ex-d housing. The Ex gap between the circuit board 11 and the upper housing part 12 and/or the lower housing part 26 prevents a flame transmission. Hence, with the arrangement in accordance with the invention, the potting of non-intrinsically safe electrical circuits or electronic assemblies becomes superfluous. Errors that could occur due to tensions between the casting compound and the circuit board or the electrical components 18 are thereby precluded.

It will be understood that the use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e. meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

A preferred embodiment of this invention is described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Moreover, any combination of the above-described elements in all possible variations thereof is encompassed by the invention unless otherwise indicated herein or otherwise clearly contradicted by context.

1-11. (canceled)

12. An explosion protected circuit board assembly (10) comprising:
a circuit board (11) having a carrier plate (13) with conductor strips (16, 17),
an electrical component (18) mounted on the circuit board carrier plate (13), and
a first housing part (12) supported a side of said circuit board and defining a hollow space (22) for encasing the electrical component (18) in an explosion-proof manner.

13. The explosion protected circuit board assembly of claim 12 in which said circuit board (11) carries at least on additional electrical component (41, 42, 43) outside the housing part (12)

14. The explosion protected circuit board assembly of claim 12 in which said housing part (12) is fastened to said circuit board (11).

15. The explosion protected circuit board assembly of claim 12 in which said circuit board (11) supports an additional housing part (26) on a side (15) opposite the side said first housing part (12) is supported.

16. The explosion protected circuit board assembly of claim 15 in which said housing parts (12, 26) are connected to said circuit board (11).

17. The explosion protected circuit board assembly of claim 12 in which said first housing part (12) has an edge (23) that is seated no one flat side (14) of said circuit board (11), at least one of said conductor strips (16) being disposed between said edge (23) of the housing part (12) and said circuit board (11) and extending out of a region of the circuit board (11) encased by said housing part (12) into a region of the circuit board (11) that is not encased by the housing part (12).

18. The explosion protected circuit board assembly of claim 12 including a casting compound (48) on at least one side (14) of the circuit board (11).

19. The explosion protected circuit board assembly of claim 12 including a casting compound (48) on both sides of said circuit board (11).

20. The explosion protected circuit board assembly of claim 15 including a fastener (24, 31) extending through said circuit board (11) for connecting said first housing part (12) to said additional housing part (26).

21. The explosion protected circuit board assembly of claim 12 including a loose filling of particulate material (40) in the hallow space (22) defined by said first housing part (12).

22. The explosion protected circuit board assembly of claim 12 in which said circuit board (11) and first housing part (12) are glued together.
